(19) United States
(12) Patent Application Publication
(10) Pub. No.: US 2025/0198042 A1
(43) Pub. Date: Jun. 19, 2025

(54) APPARATUS FOR PROCESSING SUBSTRATE, METHOD OF CONTROLLING APPARATUS FOR PROCESSING SUBSTRATE, AND STORAGE MEDIUM WITH PROGRAM STORED THEREIN

(71) Applicant: EBARA CORPORATION, Tokyo (JP)

(72) Inventors: Shunsuke KAGAYA, Tokyo (JP); Ryuya KOIZUMI, Tokyo (JP)

(21) Appl. No.: 18/955,680

(22) Filed: Nov. 21, 2024

(30) Foreign Application Priority Data
Dec. 15, 2023 (JP) 2023-212458

(51) Int. Cl. C25D 21/12; H01L 21/67

(52) U.S. Cl. CPC C25D 21/12; H01L 21/6723

(57) ABSTRACT

An apparatus for processing a substrate, comprises a plurality of processing modules, each configured to perform processing of a substrate; a transfer machine configured to transfer the substrate; and a controller configured to create a transfer time table, which causes the substrate to be transferred between the plurality of processing modules and to be processed, and to control the transfer of the substrate by the transfer machine and control the processing of the substrate in each of the plurality of processing modules, based on the transfer time table, wherein when it is determined that a retry or an extension of a cleaning process is expected to occur or occurs in a first processing module out of the plurality of processing modules, the controller sets the first processing module to be non-usable and updates the transfer time table, such that a subsequent substrate does not pass through the first processing module.

### TECHNICAL FIELD

The present disclosure relates to an apparatus for processing a substrate, a method of controlling the apparatus for processing the substrate, and a storage medium with a program stored therein and configured to cause a computer to perform the method of controlling the apparatus for processing the substrate.

### BACKGROUND ART

There are a lot of cleaning processes in a semiconductor manufacturing apparatus. In some cases, there is a requirement for cleaning a processing module (tank) of the apparatus, as well as a requirement for cleaning of a substrate (for example, a wafer). Cleaning of a processing module is performed in a time period after a substrate is processed in the processing module and before another substrate is placed in the processing module. For example, Japanese Patent No. 7142812B (PTL 1) describes cleaning of a contact of a substrate holder after cleaning of a substrate that is subjected to a plating process in a plating module.

### CITATION LIST

### Patent Literatures

PTL 1: Japanese Patent No. 7142812B

### SUMMARY OF INVENTION

### Technical Problem

A cleaning time is adjusted and set to basically complete the cleaning process in a fixed period of time. In some cases, however, a retry or an extension of the cleaning process is required for some reason. Any substrate is not allowed to be placed in a processing module that is engaged in cleaning. This delays the time when a next substrate uses (is placed in) the processing module. In this case, there is a need to wait until module cleaning is completed and the processing module becomes usable again. This is likely to reduce the throughput of the apparatus. Furthermore, in the case where a substrate that is planned to use the processing module next is present in a previous processing module or in a processing module on an upstream side, a long time period elapses between processes. (This means that a process constraint/an upper limit of a leaving time after processing cannot be kept). This is likely to cause corrosion of the substrate.

One object of the present disclosure is to solve at least one of the problems described above. One object of the present disclosure is to suppress a reduction in the throughput of an apparatus, even on the occurrence of a retry or an extension of module cleaning. One object of the present disclosure is to reduce the possibility that a process constraint cannot be kept, even on the occurrence of a retry or an extension of module cleaning.

### Solution to Problem

According to one aspect of the present disclosure, there is provided an apparatus for processing a substrate, comprising: a plurality of processing modules, each being configured to perform processing of a substrate; a transfer machine configured to transfer the substrate; and a controller configured to create a transfer time table, which causes the substrate to be transferred between the plurality of processing modules and to be processed, and to control the transfer of the substrate by the transfer machine and control the processing of the substrate in each of the plurality of processing modules, based on the transfer time table, wherein when it is determined that a retry or an extension of a cleaning process is expected to occur or occurs in a first processing module out of the plurality of processing modules, the controller sets the first processing module to be non-usable and updates the transfer time table, such that a subsequent substrate does not pass through the first processing module.

### BRIEF DESCRIPTION OF DRAWINGS

FIG. 1 is a perspective view illustrating the overall configuration of a plating apparatus as one example of a substrate processing apparatus;

FIG. 2 is a plan view illustrating the overall configuration of the plating apparatus as one example of the substrate processing apparatus;

FIG. 3 is an explanatory diagram illustrating the control configuration of the plating apparatus as one example of the substrate processing apparatus;

FIG. 4 is a schematic diagram illustrating the outline of scheduling by a transfer scheduler;

FIG. 5 is a schematic diagram illustrating a concrete example of inputs and outputs of the transfer scheduler;

FIG. 6 is a schematic diagram illustrating the functional configuration of the transfer scheduler;

FIG. 7 is a schematic diagram illustrating the configuration of a plating module;

FIG. 8 is explanatory diagrams illustrating one example of a cleaning process in the plating module;

FIG. 9A is an explanatory diagram illustrating a flow of substrate transfer at the time of a retry of cleaning;

FIG. 9B is an explanatory diagram illustrating the flow of substrate transfer at the time of the retry of cleaning;

FIG. 9C is an explanatory diagram illustrating the flow of substrate transfer at the time of the retry of cleaning;

FIG. 9D is an explanatory diagram illustrating the flow of substrate transfer at the time of the retry of cleaning;

FIG. 9E is an explanatory diagram illustrating the flow of substrate transfer at the time of the retry of cleaning;

FIG. 9F is an explanatory diagram illustrating the flow of substrate transfer at the time of the retry of cleaning;

FIG. 9G is an explanatory diagram illustrating the flow of substrate transfer at the time of the retry of cleaning;

FIG. 9H is an explanatory diagram illustrating the flow of substrate transfer at the time of the retry of cleaning;

FIG. 9I is an explanatory diagram illustrating the flow of substrate transfer at the time of the retry of cleaning;

FIG. 10 is a flowchart showing a flow of transfer scheduling;

FIG. 11 is a flowchart showing transfer scheduling of a new job;

FIG. 12 is a flowchart showing transfer scheduling at the time of a retry of module cleaning;

FIG. 13 is a flowchart showing transfer scheduling on completion of module cleaning; and

FIG. 14 is a plan view illustrating the overall configuration of a substrate processing apparatus according to another embodiment.

### DESCRIPTION OF EMBODIMENTS

The following describes one embodiment of the present disclosure with reference to the drawings. In the respective embodiments described below, identical or equivalent members are expressed by identical reference signs with omission of duplicated description. In the description hereof, the expressions such as “upper” or “upward”, “lower” or “downward”, “left” or “leftward” and “right” and “rightward” are used. These expressions indicate the positions, the orientations, and the directions on the sheet surface of the illustrated drawings for the purpose of explanation, and these positions, orientations and directions may be different from those in the actual arrangement, for example, when using the apparatus.

A plating apparatus is described below as one example of a substrate processing apparatus. The substrate processing apparatus is applicable to a plating apparatus, a CMP apparatus, an etching apparatus and other arbitrary substrate processing apparatuses configured to transfer substrates between a plurality of processing modules on the basis of a transfer schedule. The plating apparatus may be either an electrolytic plating apparatus or a non-electrolytic plating apparatus. The plating apparatus may be a horizontal or traverse plating apparatus (cup type/face-down type) configured to plate a substrate horizontally held therein, a vertical plating apparatus (dip type) configured to plate a substrate vertically held therein, or any of other arbitrary plating apparatuses. The substrate herein may be a substrate or an object to be processed in a circular shape, in a polygonal shape such as a rectangular shape, or in any of other arbitrary shapes. The substrate herein may be a semiconductor wafer, a glass substrate, a liquid crystal substrate, a printed circuit board or any of other arbitrary objects to be processed.

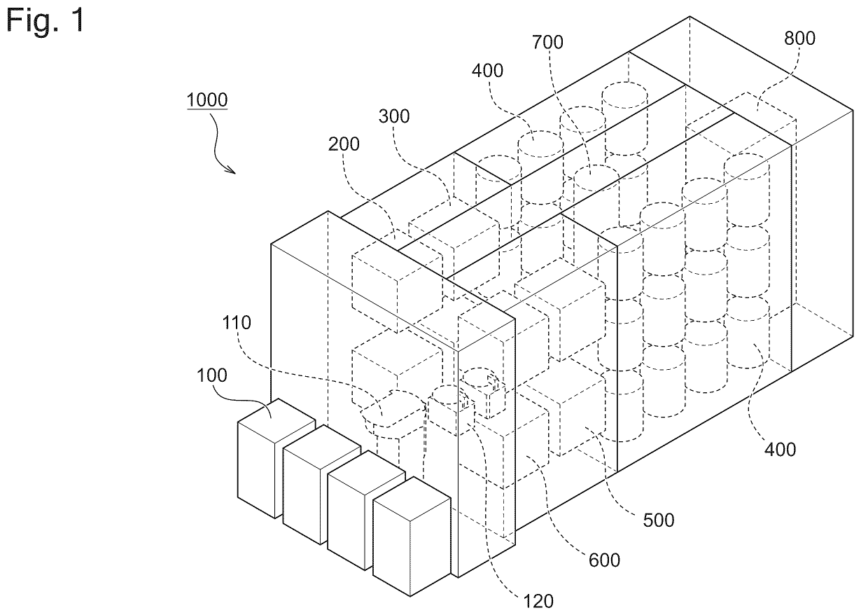

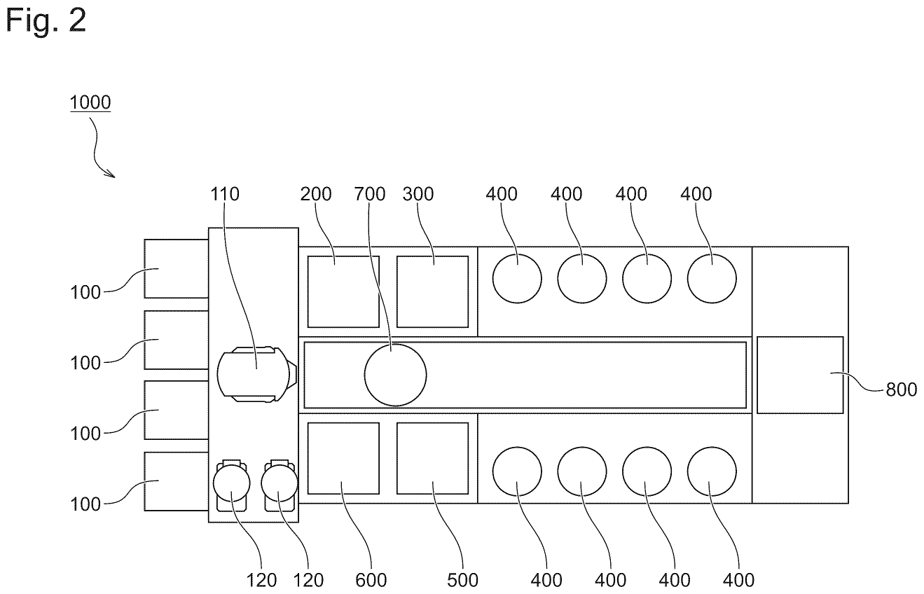

FIG. 1 is a perspective view illustrating the overall configuration of a plating apparatus 1000 as one example of a substrate processing apparatus. FIG. 2 is a plan view illustrating the overall configuration of the plating apparatus 1000 as one example of the substrate processing apparatus. As illustrated in FIGS. 1 and 2, a plating apparatus 1000 includes load ports 100, a transfer robot 110, aligners 120, pre-wet modules 200, pre-soak modules 300, plating modules 400, cleaning modules 500, spin rinse dryers 600, a transfer device 700, and a control module 800.

The load port 100 is a module for loading a substrate housed in a cassette, such as a FOUP (not illustrated), to the plating apparatus 1000 and unloading the substrate from the plating apparatus 1000 to the cassette. While the four load ports 100 are arranged in the horizontal direction in this embodiment, the number of load ports 100 and arrangement of the load ports 100 are arbitrary. The transfer robot 110 is a robot for transferring the substrate that is configured to grip or release the substrate between the load port 100, the aligner 120, the pre-wet module 200, and the spin rinse dryers 600. The transfer robot 110 and the transfer device 700 can perform delivery and receipt of the substrate via a temporary placement table (not illustrated) to grip or release the substrate between the transfer robot 110 and the transfer device 700.

The aligner 120 is a module for adjusting a position of an orientation flat, a notch, and the like of the substrate in a predetermined direction. While the two aligners 120 are disposed to be arranged in the horizontal direction in this embodiment, the number of aligners 120 and arrangement of the aligners 120 are arbitrary. The pre-wet module 200 wets a surface to be plated of the substrate before a plating process with a process liquid, such as pure water or deaerated water, to replace air inside a pattern formed on the surface of the substrate with the process liquid. The pre-wet module 200 is configured to perform a pre-wet process to facilitate supplying the plating solution to the inside of the pattern by replacing the process liquid inside the pattern with a plating solution during plating. While the two pre-wet modules 200 are disposed to be arranged in the vertical direction in this embodiment, the number of pre-wet modules 200 and arrangement of the pre-wet modules 200 are arbitrary.

For example, the pre-soak module 300 is configured to remove an oxidized film having a large electrical resistance present on, a surface of a seed layer formed on the surface to be plated of the substrate before the plating process by etching with a process liquid, such as sulfuric acid and hydrochloric acid, and perform a pre-soak process that cleans or activates a surface of a plating base layer. While the two pre-soak modules 300 are disposed to be arranged in the vertical direction in this embodiment, the number of pre-soak modules 300 and arrangement of the pre-soak modules 300 are arbitrary. The plating module 400 performs the plating process on the substrate. There are two sets of the 12 plating modules 400 arranged by three in the vertical direction and by four in the horizontal direction, and the total 24 plating modules 400 are disposed in this embodiment, but the number of plating modules 400 and arrangement of the plating modules 400 are arbitrary.

The cleaning module 500 is configured to perform a cleaning process on the substrate to remove the plating solution or the like left on the substrate after the plating process. While the two cleaning modules 500 are disposed to be arranged in the vertical direction in this embodiment, the number of cleaning modules 500 and arrangement of the cleaning modules 500 are arbitrary. The spin rinse dryer 600 is a module for rotating the substrate after the cleaning process at high speed and drying the substrate. While the two spin rinse dryers are disposed to be arranged in the vertical direction in this embodiment, the number of spin rinse dryers and arrangement of the spin rinse dryers are arbitrary. The transfer device 700 is a device for transfer the substrate between the plurality of modules inside the plating apparatus 1000. The control module 800 is configured to control the plurality of modules in the plating apparatus 1000 and can be configured of, for example, a general computer including input/output interfaces with an operator or a dedicated computer.

An example of a sequence of the plating processes by the plating apparatus 1000 will be described. First, the substrate housed in the cassette is loaded on the load port 100. Subsequently, the transfer robot 110 grips the substrate from the cassette at the load port 100 and transfers the substrate to the aligners 120. The aligner 120 adjusts the position of the orientation flat, the notch, or the like of the substrate in the predetermined direction. The transfer robot 110 grips or releases the substrate whose direction is adjusted with the aligners 120 to the pre-wet module 200.

The transfer device 700 transfers the substrate received from the transfer robot 110 to the pre-wet module 200. The pre-wet module 200 performs the pre-wet process on the substrate. The transfer device 700 transfers the substrate on which the pre-wet process has been performed to the pre-soak module 300. The pre-soak module 300 performs the pre-soak process on the substrate. The transfer device 700 transfers the substrate on which the pre-soak process has been performed to the plating module 400. The plating module 400 performs the plating process on the substrate.

The transfer device 700 transfers the substrate on which the plating process has been performed to the cleaning module 500. The cleaning module 500 performs the cleaning process on the substrate. The transfer device 700 transfers the substrate on which the cleaning process has been performed to the spin rinse dryer 600. The spin rinse dryer 600 performs the drying process on the substrate. The transfer robot 110 receives the substrate from the spin rinse dryer 600 and transfers the substrate, on which the drying process is performed, to the cassette at the load port 100. Finally, the cassette housing the substrate is unloaded from the load port 100.

The configuration of the plating apparatus 1000 described above with reference to FIG. 1 and FIG. 2 is only illustrative and is not limited to the configuration of FIG. 1 and FIG. 2.

### <Control Configuration>

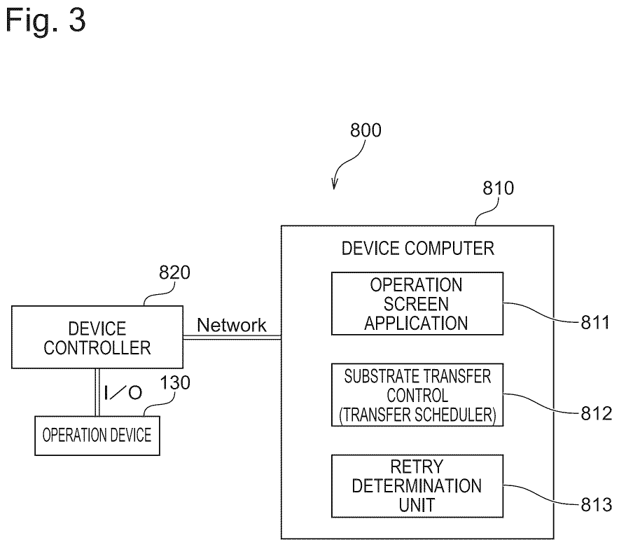

FIG. 3 is an explanatory diagram illustrating the control configuration of the plating apparatus 1000 as one example of the substrate processing apparatus. According to the embodiment, part or the entirety of the functions of the control module 800 may be configured by a hardware structure, such as an ASIC. Part or the entirety of the functions of the control module 800 may be configured by a PLC, a sequencer or the like. Part or the entirety of the control module 800 may be placed inside and/or outside of the housing of the plating apparatus 1000. Part or the entirety of the control module 800 is connected by wire and/or wirelessly with the respective parts of the plating apparatus in a communicable manner.

As shown in FIG. 3, the plating apparatus 1000 may be configured to include a device computer 810 and a device controller 820, which serve as the control module 800 of controlling the respective parts of the apparatus. The device computer 810 is connected with the device controller 820 via a wired or wireless network, a cable or the like. Various operation devices 130 of the plating apparatus 1000 are connected with the device controller 820 via a predetermined interface I/O. The device computer 810 and the device controller 820 cooperate with each other to perform controls of the various operation devices 130 of the plating apparatus 1000. Control signals from the device computer 810 are sent to the device controller 820 via the network, so as to control the various operation devices 130 via the device controller 820. The device computer 810 is configured to be communicable by wire or wirelessly with a non-illustrated upper level controller (host computer) that comprehensively controls the plating apparatus 1000 and other relevant apparatuses and to exchange data with a database of the upper level controller.

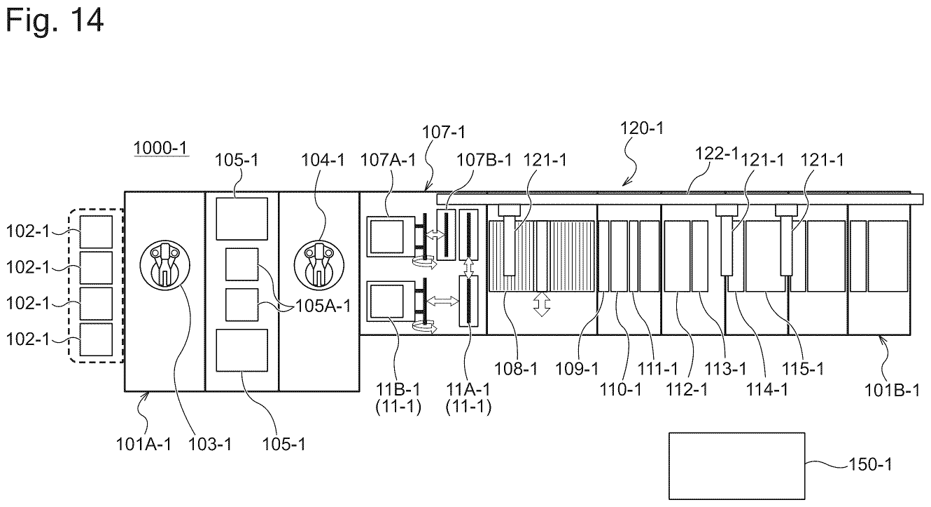

The device controller 820 is configured by, for example, a PLC, a sequencer or the like to control the various operation devices of the plating apparatus 1000, based on control commands, set parameters, a transfer time table and the like from the device computer 810. The various operation devices of the plating apparatus 1000 herein include the transfer robot 110, the transfer device 700 (hereinafter also referred to as the transfer machine 700 or the transporter 700) and other devices. The configuration of the embodiment is provided with one transfer machine 700. The following description is, however, also applicable to a configuration provided with a plurality of transfer machines (for example, a configuration of FIG. 14).

The device computer 810 includes a memory (not shown) configured to store therein a variety of set data, such as machine constants (machine parameters), and a variety of programs; and a CPU (not shown) configured to execute the programs in the memory. The device computer 810 may be provided with an input/output interface that includes an output device, such as a display, and an input device including a keyboard, a mouse and the like. A storage medium that configures the memory may include any volatile storage medium and/or any non-volatile storage medium. The storage medium may include one or a plurality of arbitrary storage media, for example, a ROM, a RAM, a hard disk, a CD-ROM, a DVD-ROM, and a flexible disk.

As shown in FIG. 3, the programs stored in the memory include, for example, software that configures an operation screen application 811 in the device computer 810; and scheduling software that configures a module called a transfer scheduler 812 in the device computer 810. The scheduling software herein is scheduling software configured to compute a transfer schedule (transfer time table) and is executed by the CPU to configure the transfer scheduler 812. The transfer scheduler 812 serves as a substrate transfer controller to create a transfer time table for performing transfer control that provides a maximum throughput, with referring to, for example, a predetermined operation time of each of the transfer machines and the like, processing conditions (processing recipe) of a target substrate that receives (is subject to) an instruction to be processed, and the number of substrates to be processed. The operation screen application 811 shows the transfer time table and the like described later, on the display. This operation screen application 811 enables inputs from an operator (for example, selection of the recipe) to be received and accepted.

The programs stored in the memory also include software that configures a retry determination unit 813 in the device computer 810. The retry determination unit 813 manages a retry event and a completion event of module cleaning in a processing module. The retry determination unit 813 determines the result of module cleaning in a processing module (contact cleaning in the plating module 400 in this example), issues a module cleaning retry event or a module cleaning completion event, and notifies the transfer scheduler 812 of the module cleaning retry event or the module cleaning completion event. When it is determined that module cleaning is expected to be not completed or has not been completed within a set cleaning time, during the module cleaning or at the end of the module cleaning, the retry determination module 813 issues a module cleaning retry event to perform a retry of the module cleaning (including extension of the cleaning time). In general, the cleaning time (set time) of module cleaning is stored as a machine constant in the memory. In place of or in addition to such storage, the cleaning time of module cleaning may be set in a recipe. When it is determined that module cleaning is expected to be not completed or has not been completed within the set cleaning time, during first module cleaning or retried module cleaning(s) or at the end of the first module cleaning or the retried module cleaning(s), the retry determination module 813 issues a module cleaning retry event to perform a retry of module cleaning (including extension of the cleaning time). The first module cleaning herein means first module cleaning prior to a retry. When it is determined that module cleaning is expected to be successfully completed or has successfully been completed, during the first module cleaning or the retried module cleaning(s) or at the end of the first module cleaning or the retried module cleaning(s), the retry determination module 813 issues a module cleaning completion event. This means that the retry determination unit 813 repeatedly issues the module cleaning retry event and repeats the retry of module cleaning until the module cleaning is successfully completed. In the case where the retry of module cleaning (including extension of the cleaning time) is repeated multiple times until the module cleaning is successfully completed, the retry determination unit 813 may issue a cleaning retry event only for a first cleaning retry (may not issue cleaning retry events for second and subsequent cleaning retries). A modified configuration may set an upper limit number of times to the number of retries and may issue a cleaning error in the case where module cleaning is not completed even after repetition of module cleaning the upper limit number of times.

The retry determination unit 813 configures part of the control module 800 as described above. The retry determination unit 813 is not necessarily required to be provided in the device computer 810 but may be provided in the device controller 820, in a processing module as an object of retry determination, or in another location.

The programs stored in the memory may further include programs that control processes of the substrates in the respective processing modules and tanks (including a program that performs control of the plating process in the plating module 400), and other control programs.

### <Outline of Scheduling by Transfer Scheduler>

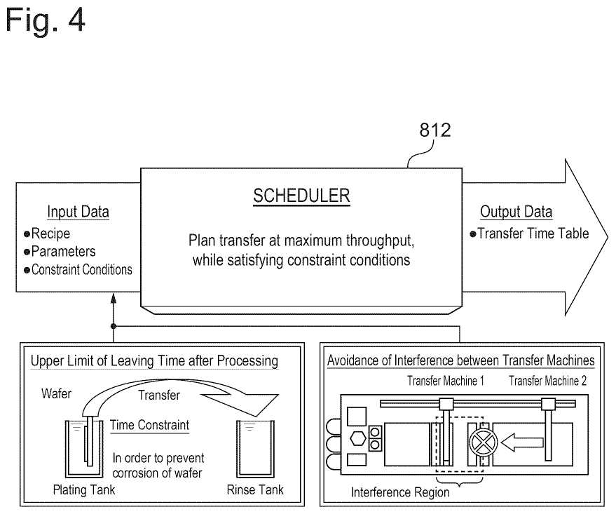

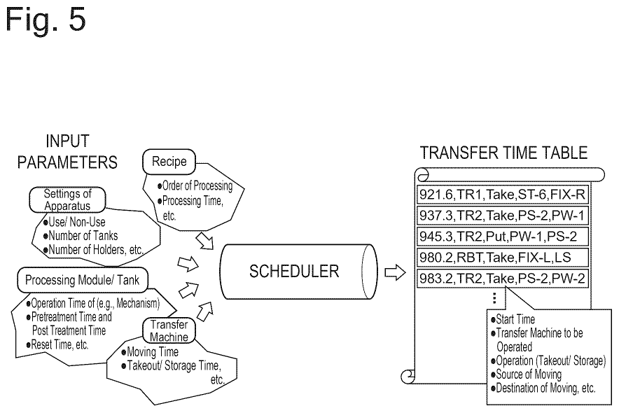

FIG. 4 is a schematic diagram illustrating the outline of scheduling by the transfer scheduler 812. FIG. 5 is a schematic diagram illustrating a concrete example of inputs and outputs of the transfer scheduler 812.

As shown in FIG. 4, the transfer scheduler 812 receives inputs of a recipe, parameters other than the recipe and constraint conditions as input data and creates a transfer time table at a maximum throughput while satisfying the constraint conditions. The constraint conditions herein include an “upper limit of leaving time after processing” in each of the processing tanks and an “interference region” set for the purpose of avoiding a collision between transfer machines. The upper limit of leaving time after processing denotes a time constraint set to prevent corrosion of a substrate in each of the processing tanks and is defined as a time period until the substrate is unloaded from the processing tank after completion of processing in the processing tank. The interference region is an area set to prevent collision between a plurality of transfer machines and is set to prevent any other transfer machine from moving to an interference region of each transfer machine and thereby prevent the respective transfer machines from approaching each other within a predetermined distance. The plating apparatus 1000 of the embodiment is provided with one transfer machine 700 (shown in FIG. 1 and FIG. 2), so that the setting of an interference region is omitted. A plating apparatus of FIG. 14 described later is, however, provided with three transfer machines 121, so that an interference region is set for each of the transfer machines.

In FIG. 5, a recipe and parameters other than the recipe are collectively called input parameters. As shown in FIG. 5, the recipe includes, for example, an order of processing, a processing time and the like set for each substrate or set for each job that is allocated to one or a plurality of substrates. The parameters other than the recipe include, for example, “set parameters of the apparatus”, “set parameters of the processing module/tank” and “set parameters of the transfer machine”. The recipe includes, for example, an order of processing that is a sequence of processes in the apparatus, a processing time of each process, and other conditions of each process. The set parameters of the apparatus include, for example, parameters indicating the use/non-use of each tank, the number of tanks, the number of substrate holders, and the like. The set parameters of the processing module/tank include, for example, an operation time of each of various mechanisms and the like included in the processing module/tank, a pretreatment time/post treatment time, a reset time and the like. The pretreatment time denotes a time period until a start of processing after loading of the substrate into the tank. The post treatment time denotes a time period until unloading of the substrate is allowed after processing of the substrate in the tank. The reset time denotes a time period until a tank becomes usable again after unloading of the substrate from the tank. The set parameters of the transfer machine include, for example, a moving time, a takeout/storage time and the like. This configuration of the input parameters is only illustrative and can be appropriately changed according to the configurations of the apparatus and the processes. In the description hereof, the processing module and the processing tank are used as synonyms.

As shown in FIG. 5, the transfer time table created by the transfer scheduler 812 includes, for example, a start time, a transfer machine to be operated, type of an operation (takeout/storage), a unit processing module/tank as a source of moving, and a processing module/tank as a destination of moving. The configuration of the transfer time table shown in FIG. 5 is only illustrative and can be appropriately changed according to the configurations of the apparatus and the processes.

### <Event Processes of Transfer Scheduler>

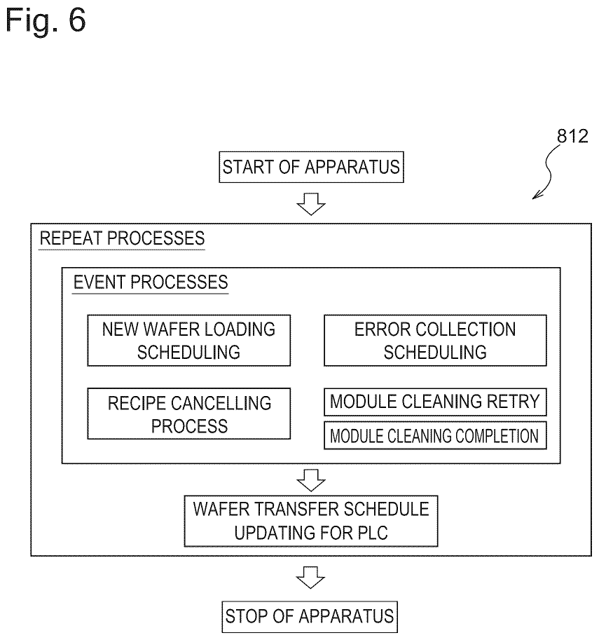

FIG. 6 is a schematic diagram illustrating the functional configuration of the transfer scheduler based on the viewpoint of event processes. As shown in FIG. 6, the transfer scheduler 812 has a “new substrate loading scheduling function”, a “recipe cancelling process function”, an “error collection scheduling function”, a “module cleaning retry scheduling function,” and a “module cleaning completion scheduling function”, as the functions of event processes that are performed repeatedly from a start of the apparatus to a stop of the apparatus. The transfer scheduler 812 of the embodiment is characterized by the “module cleaning retry scheduling function” and the “module cleaning completion scheduling function”. A “wafer transfer schedule updating function for PLC” is configured to send an updated transfer schedule (transfer time table) to the device controller 820 and to update the transfer time table that is performed by the device controller 820.

When a new substrate transfer job (hereinafter may be simply referred to as job) is issued, the transfer scheduler 812 computes a transfer time table as a transfer schedule from, for example, the configuration of the plating apparatus 1000, the recipe, the operation times of the respective modules (processing tanks and transfer machines), and the time constraints (the new substrate loading scheduling function). The substrate transfer job is allocated to one or a plurality of substrates. The transfer machine transfers the substrates according to this transfer time table. On the occurrence of an event, such as an error-induced collection process or a job cancelling process, the transfer scheduler 812 updates the transfer time table to change transfer of subsequent substrates (non-ordinary operation). The error-induced collection process is performed by the error collection scheduling function. The job cancelling process is performed by the recipe cancelling process function.

On the occurrence of a retry of module cleaning (the retry includes an extension), the transfer scheduler 812 sets the relevant processing module to be temporarily non-usable and, if there is any substrate that is planned to be processed by the relevant processing module, updates the transfer time table, such that the substrate does not pass through but goes around the relevant processing module (the module cleaning retry scheduling function). When the transfer time table includes any substrate that passes through the processing module currently engaged in cleaning, the transfer scheduler 812 updates the transfer time table, such as to use another processing module that is of an identical type with that of the processing module engaged in cleaning, and thereby minimizes a reduction in the throughput (the module cleaning retry scheduling function). On completion of a retry of module cleaning, the transfer scheduler 812 returns the relevant processing module that has completed cleaning to a usable state and updates the transfer time table, such as to use the relevant processing module again (the module cleaning completion scheduling function).

The transfer scheduler 812 is also configured to analyze the created transfer time table and to determine a throughput (the number of substrates processed per unit time). The transfer scheduler 812 is further configured to determine a rate-controlling location/bottleneck location (a location where the processing rate of the plating apparatus 1000 is controlled) from operation rates of the respective modules (the processing tanks and the transfer machines).

### <Configuration of Plating Module>

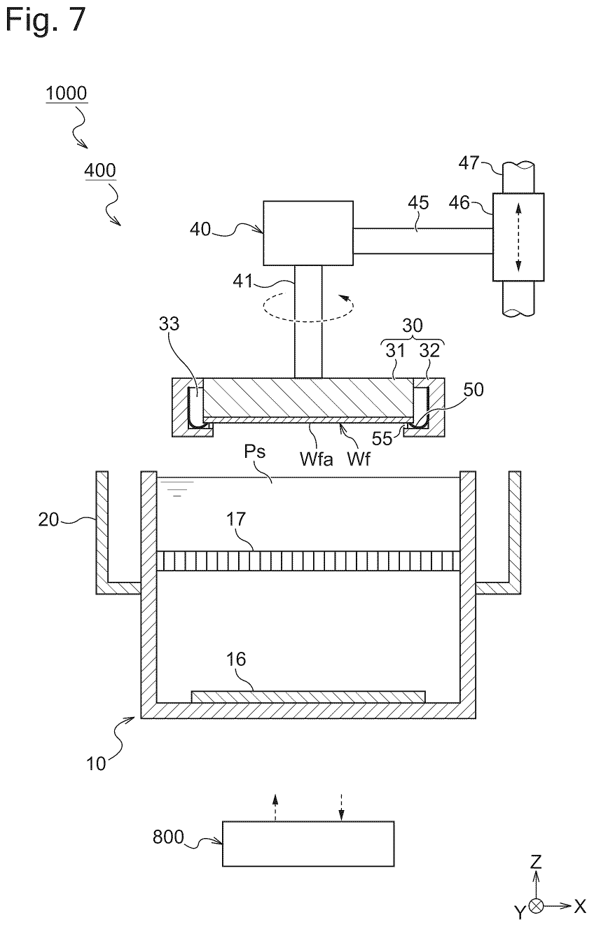

FIG. 7 is a schematic diagram illustrating the configuration of the plating module. The plating module 400 mainly includes a plating tank 10, an overflow tank 20, a substrate holder 30 that is also called a plating head, a rotation mechanism 40, a tilt mechanism 45, and a lift mechanism 46. The tilt mechanism 45 may, however, be omitted.

The plating tank 10 according to the embodiment is configured by a bottomed vessel having an opening on an upper side thereof. The plating tank 10 has a bottom wall and an outer peripheral wall, which is extended upward from an outer circumferential edge of this bottom wall and which has an opening on an upper end thereof. A plating solution Ps is stored inside of the plating tank 10. According to the embodiment, the plating tank 10 has a cylindrical shape.

The plating solution Ps may be any solution including an ion of a metal element that forms a plating film and is not specifically limited to any concrete examples. According to the embodiment, a copper plating process is employed as one example of the plating process, and a copper sulfate solution is used as one example of the plating solution Ps. According to the embodiment, the plating solution Ps includes a predetermined additive or predetermined additives. The plating solution Ps is, however, not limited to this configuration but may employ a configuration that does not include any additives.

An anode 16 is placed inside of the plating tank 10. The anode 16 is not specifically limited to any concrete type of anode but may be a soluble anode or an insoluble anode. According to the embodiment, an insoluble anode is used for the anode 16. This insoluble anode is not specifically limited to any concrete type of the insoluble anode but may be, for example, platinum or iridium oxide.

The overflow tank 20 is configured by a bottomed vessel placed outside of the plating tank 10. The overflow tank 20 temporarily stores the plating solution Ps that flows over an upper edge of the plating tank 10. In one example, the plating solution Ps in the overflow tank 20 is discharged from an outlet (not shown) for the overflow tank 20, is temporarily stored in a reservoir tank (not shown) and is again returned to the plating tank 10.

A porous resistive element (ionically resistive element) 17 is placed above the anode 16 inside of the plating tank 10. More specifically, the ionically resistive element 17 is configured by a porous plate member having a plurality of holes (pores). The plating solution Ps below the ionically resistive element 17 is allowed to pass through the ionically resistive element 17 and to flow upward to above the ionically resistive element 17. This ionically resistive element 17 is a member provided to uniformize an electric filed formed between the anode 16 and a substrate Wf. Placing this ionically resistive element 17 in the plating tank 10 readily achieves uniformization of a film thickness of a plating film (plating layer) formed on the substrate Wf. The ionically resistive element 17 is not an essential element according to the embodiment. The configuration of the embodiment may thus be not provided with the ionically resistive element 17.

As shown in FIG. 7, the substrate holder 30 is a member provided to hold the substrate Wf serving as a cathode. More specifically, the substrate holder 30 is placed above the anode 16 (further above the ionically resistive element 17 according to this embodiment). The substrate holder 30 holds the substrate Wf, such that a lower face Wfa of the substrate Wf is opposed to the anode 16 and the ionically resistive element 17. The lower face Wfa of the substrate Wf corresponds to a surface to be plated.

The substrate holder 30 according to the embodiment includes a first holding member 31, a second holding member 32, a contact 50, and a seal member 55. The substrate holder 30 holds the substrate Wf, such that the substrate Wf is placed between the first holding member 31 and the second holding member 32. The first holding member 31 holds an upper face of the substrate Wf. The second holding member 32 holds an outer circumferential part of the lower face Wfa of the substrate Wf. More specifically, the second holding member 32 of this embodiment holds the outer circumferential part of the lower face Wfa of the substrate Wf via the seal member 55. When the substrate holder 30 holds the substrate Wf, the seal member 55 closely adheres to the substrate Wf, so as to form a sealing space 33 that protects a contact region of the contact 50 and the substrate Wf (a region of the outer circumferential part of the substrate that is brought into contact with the contact 50) from the plating solution.

As shown in FIG. 7, the substrate holder 30 is connected with a rotating shaft 41 of the rotation mechanism 40. The rotation mechanism 40 is a mechanism configured to rotate the substrate holder 30. A known mechanism, such as a motor, may be used for the rotation mechanism 40. The tilt mechanism 45 is a mechanism configured to incline the rotation mechanism 40 and the substrate holder 30. A known tilt mechanism, such as a piston and a cylinder, may be used for the tilt mechanism 45. The lift mechanism 46 is supported by a support shaft 47 that is extended in a vertical direction. The lift mechanism 46 is a mechanism configured to lift up and down the substrate holder 30, the rotation mechanism 40 and the tilt mechanism 45 in the vertical direction. A known lift mechanism, such as a linear actuator, may be used for the lift mechanism 46.

In the plating process, the rotation mechanism 40 rotates the substrate holder 30 and the lift mechanism 46 moves down the substrate holder 30, so that the substrate Wf is soaked in the plating solution Ps in the plating tank 10. When the substrate Wf is soaked in the plating solution Ps, the tilt mechanism 45 may incline the substrate holder 30 as needed basis. Electricity is subsequently supplied between the anode 16 and the substrate Wf via the plating solution Ps by a non-illustrated power source. This forms a plating film on the lower face Wfa of the substrate Wf.

### <Example of Module Cleaning>

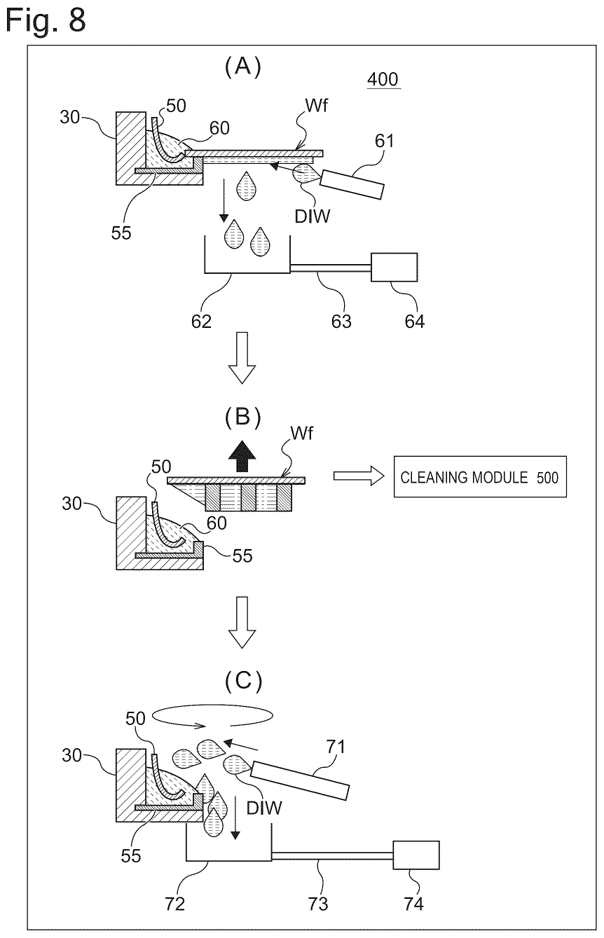

FIG. 8 is explanatory diagrams illustrating one example of a cleaning process in the plating module 400. These diagrams illustrate an example of a wet contact process that performs a plating process of the substrate in the state that the contact 50 of the substrate holder 30 is covered with DIW 60. The plating process may, however, be a dry contact process that performs the plating process without covering the contact 50 of the substrate holder 30 with a liquid.

In the state that the substrate Wf is held by the substrate holder 30, the substrate Wf after completion of the plating process in the plating module 400 is lifted up to above the liquid surface of the plating solution and is cleaned with a cleaning liquid (for example, DIW that is one example of pure water) supplied from a cleaning nozzle 61 (shown in FIG. 8(A)). The cleaning liquid after being used for cleaning is collected in a liquid receiving tray 62 that is placed below the substrate Wf, and is discharged through a waste liquid pipe 63. The electrical conductivity of the collected cleaning liquid (pure water) is measured by a conductivity meter 64 provided in the liquid receiving tray 62 and/or the waste liquid pipe 63. When the electrical conductivity of the cleaning after use is lowered below a predetermined value, cleaning of the substrate Wf is completed. The cleaning nozzle 61 and the liquid receiving tray 62 may be configured, for example, to be moved to below the substrate holder when the substrate holder 30 is lifted up and to be retreated from below the substrate holder 30 after the cleaning process.

The substrate Wf after cleaning is detached from the substrate holder 30. The detached substrate Wf is sequentially transferred to the cleaning module 500 and the spin rinse dryer 600 to be subjected to a cleaning process and a drying process and is subsequently transferred to a cassette of the load port 100 (shown in FIG. 8(B)).

After detachment of the substrate Wf, the contact 50 (and the seal member 55) of the substrate holder is cleaned with a predetermined amount of a cleaning liquid (for example, DIW) supplied from a cleaning nozzle 71 (shown in FIG. 8(C)). In this process, the substrate holder 30 and/or the cleaning nozzle 71 are rotated by at least one circle, in order to cause pure water to be uniformly supplied to the contact 50. The cleaning liquid after being used for cleaning is collected in a liquid receiving tray 72 that is placed below the substrate Wf, and is discharged through a waste liquid pipe 73. The electrical conductivity of the collected cleaning liquid (DIW) is measured by a conductivity meter 74 provided in the liquid receiving tray 72 and/or the waste liquid pipe 73, and the measured electrically conductivity is given to the control module 800. The control module 800 (the retry determination unit) determines whether the measured electrical conductivity of the cleaning liquid is lower than a reference value and, when the electrical conductivity of the cleaning liquid becomes lower than the reference value, determines that cleaning of the contact (module cleaning) is completed.

In the case where cleaning of the contact 50 is not completed (i.e., In the case where the electrical conductivity of the cleaning liquid after use is not lowered below the predetermined value) by one cleaning process set in a recipe, a retry of cleaning (including extension of the cleaning time) is performed (i.e., the cleaning process is performed again and/or the cleaning time is extended). In the case where cleaning is not completed (i.e., In the case where the electrical conductivity of the cleaning liquid after use is not lowered below the predetermined value) by one retry of cleaning (one extension of the cleaning time), the retry of cleaning is repeated until cleaning is completed (until the electrical conductivity of the cleaning liquid after use is lowered below the predetermined value). Accordingly, one retry of cleaning or multiple retries of cleaning are performed.

For example, when it is determined that the electrical conductivity of the cleaning solution is expected not to become lower than the reference value or has not become lower than the reference value within a set cleaning time, during a first contact cleaning process or at the end of the first contact cleaning process, the retry determination unit 813 issues a module cleaning retry event and notifies the transfer scheduler 812 of the module cleaning retry event. The determination prior to termination of the cleaning process may be performed, for example, by determining (estimating) whether the electrical conductivity of the cleaning liquid becomes lower than the reference value within the cleaning time in the middle of the cleaning process, based on the current electrical conductivity of the cleaning liquid and a remaining time of the cleaning time.

When it is determined that the electrical conductivity of the cleaning solution is expected not to become lower than the reference value or has not become lower than the reference value within the cleaning time, during a first retry or multiple times of retries of contact cleaning or at the end of the first retry or the multiple times of retries of contact cleaning, the retry determination unit 813 also issues a module cleaning retry event in order to perform another retry of module cleaning (including a further extension of the cleaning time) and notifies the transfer scheduler 812 of the module cleaning retry event. The determination prior to termination of the cleaning process may be performed, for example, by determining (estimating) whether the electrical conductivity of the cleaning liquid becomes lower than the reference value within the cleaning time in the middle of the cleaning process, based on the current electrical conductivity of the cleaning liquid and a remaining time of the cleaning time.

When it is determined that the electrical conductivity of the cleaning solution is expected to become lower than the reference value or has become lower than the reference value within the cleaning time, during the first contact cleaning or during a first retry or multiple times of retries of contact cleaning, or at the end of the first contact cleaning or at the end of the first retry or the multiple times of retries of contact cleaning, the retry determination unit 813 issues a module cleaning completion event. The determination prior to termination of the cleaning process may be performed, for example, by determining (estimating) whether the electrical conductivity of the cleaning liquid becomes lower than the reference value within the cleaning time in the middle of the cleaning process, based on the current electrical conductivity of the cleaning liquid and a remaining time of the cleaning time.

The retry determination unit 813 repeatedly issues a module cleaning retry event and performs retries of module cleaning until contact cleaning is successfully completed. A modified configuration may set an upper limit number of times to the number of retries and may issue a cleaning error in the case where module cleaning is not completed even after repetition of module cleaning by the upper limit number of times. The cleaning time of each retry or each extension may be identical with or may be different from the cleaning time of the first cleaning process (the cleaning process prior to the retry). The cleaning times of the respective retries (including respective extensions) may be entirely or may be partly identical with one another or may be different from one another.

As described above, the cleaning time is adjusted and set to basically complete the cleaning process in a fixed period of time. In some cases, however, a retry (including an extension) of the cleaning process is required for some reason. The configuration of this embodiment accordingly performs transfer scheduling as described below. On the occurrence of a retry of module cleaning, the transfer scheduler 812 sets the relevant processing module (for example, the plating module 400) to be temporarily non-usable and, if there is any substrate that is planned to be processed by the relevant processing module, updates the transfer time table, such that the substrate does not pass through but goes around the relevant processing module. When the transfer time table includes any substrate that passes through the processing module currently engaged in cleaning, the transfer scheduler 812 updates the transfer time table, such as to use another processing module that is of an identical type with that of the processing module engaged in cleaning. On completion of a retry of module cleaning, the transfer scheduler 812 returns the relevant processing module that has completed cleaning to a usable state and updates the transfer time table, such as to use the relevant processing module again.

### <Flow of Substrate Transfer at Retry of Cleaning>

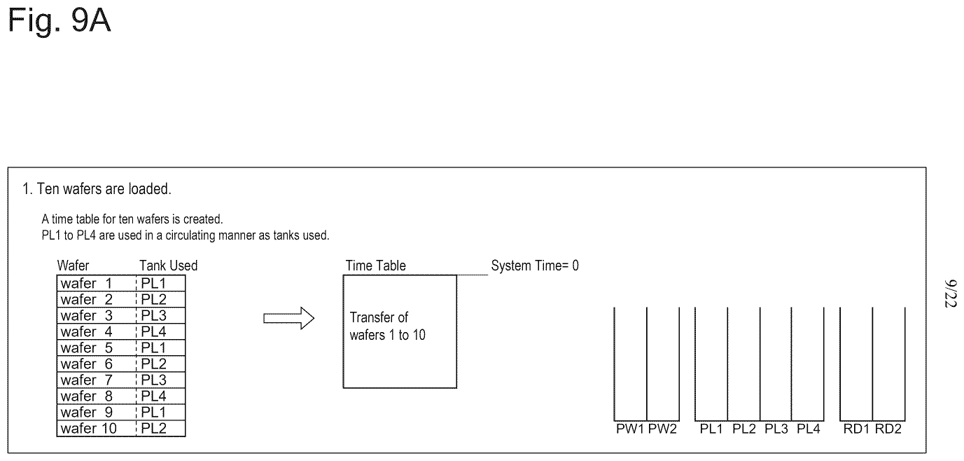

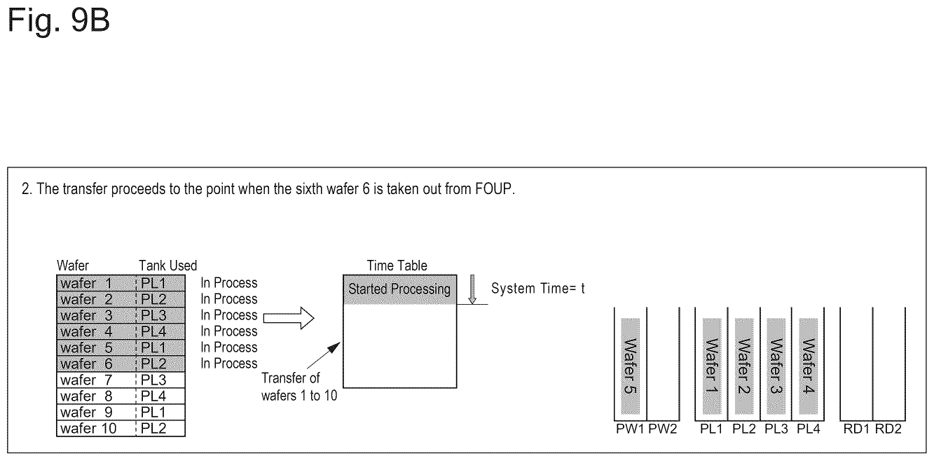

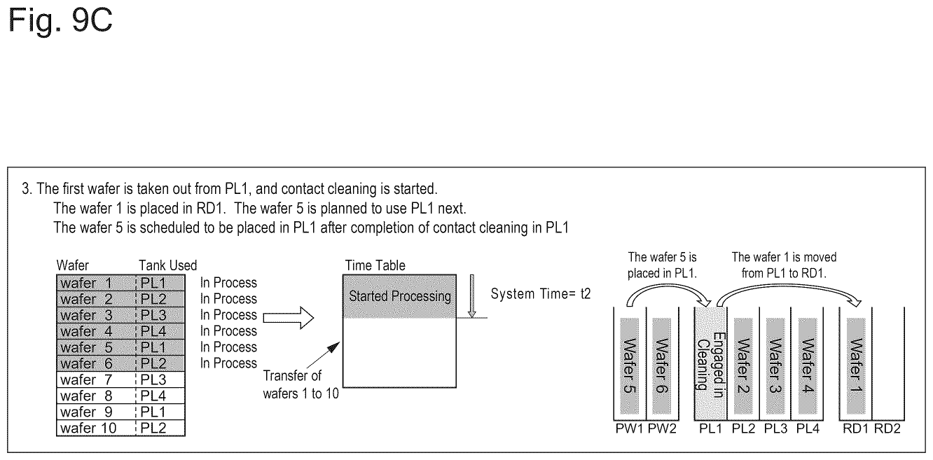

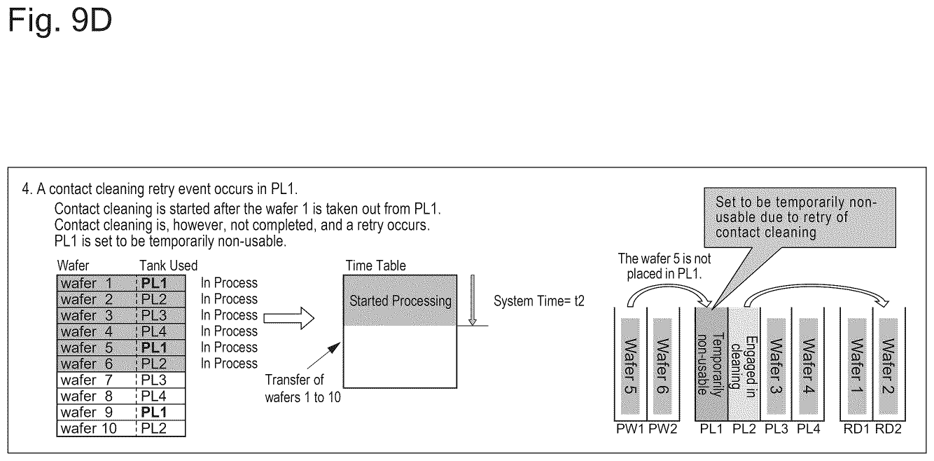

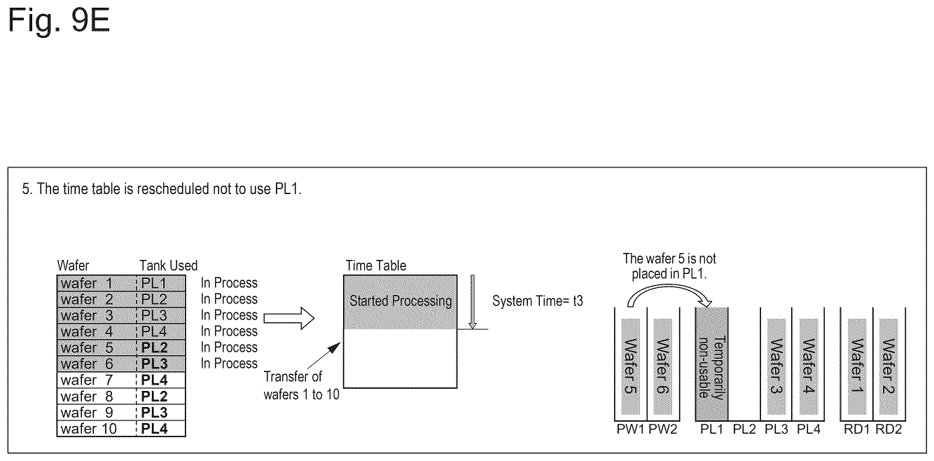

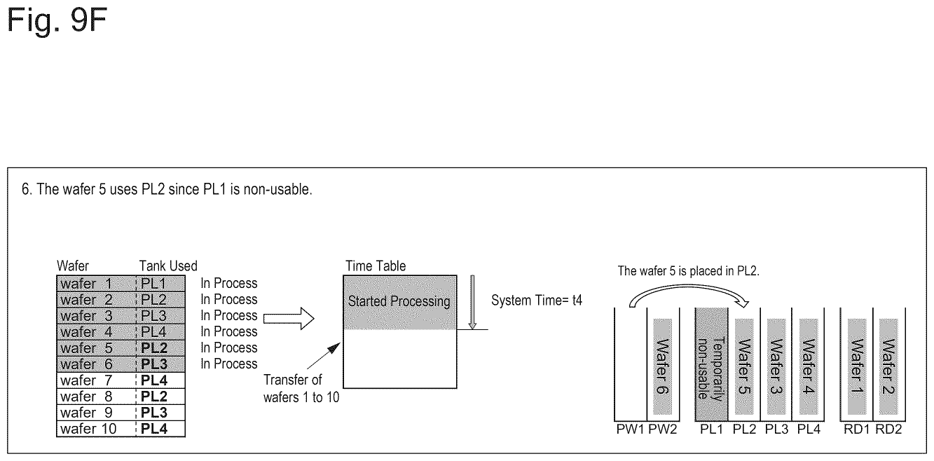

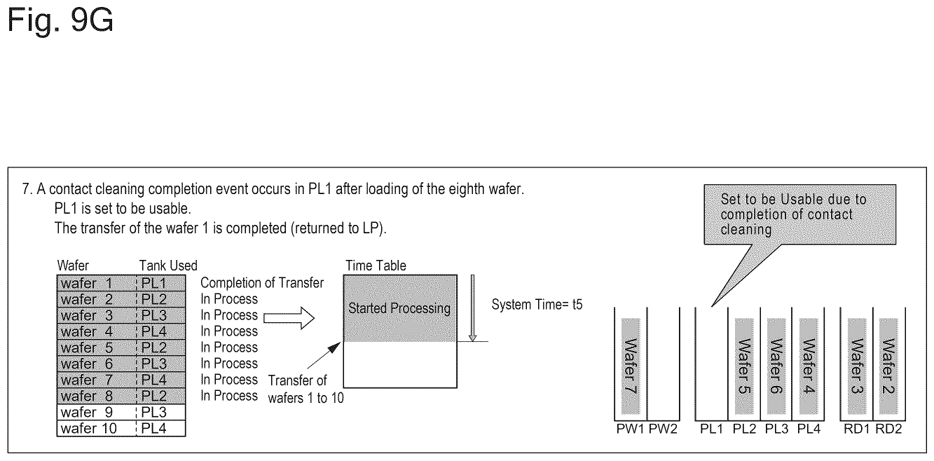

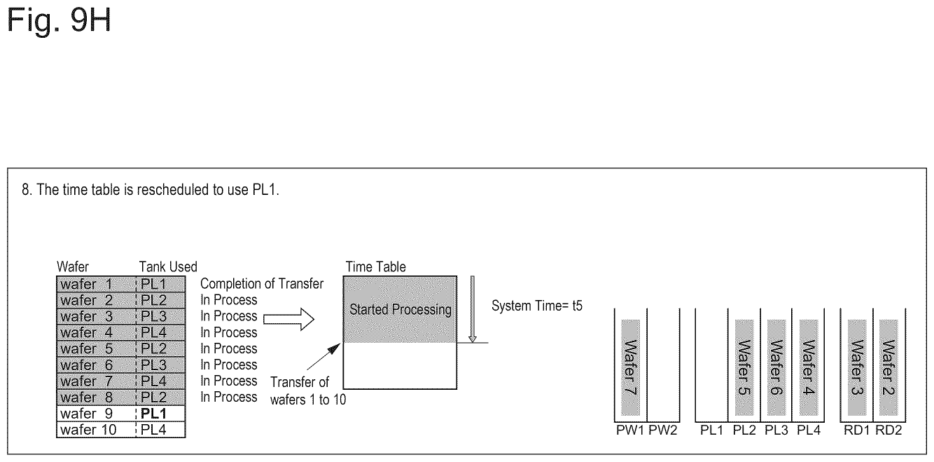

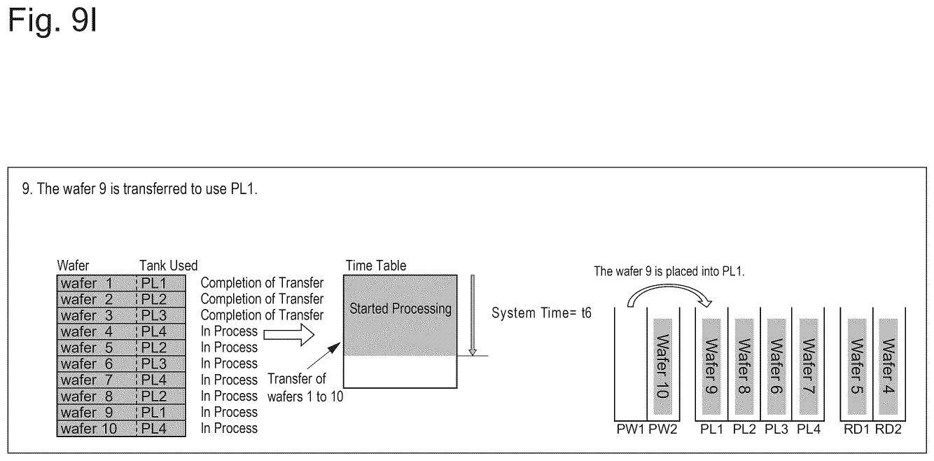

FIGS. 9A to 9I are explanatory diagrams illustrating a flow of substrate transfer at the time of a retry of cleaning. In the illustrated example, the substrate Wf is a wafer, and ten wafers (wafer 1 to wafer 10) are loaded to the plating apparatus 1000. In these diagrams, PW1 to PW2 represent the pre-wet modules 200; PL1 to PL4 represent the plating modules 400; and RD1 to RD2 represent the spin rinse dryers 600. For the convenience of explanation, this illustrated example shows a simplified case where the processing in the pre-soak modules 300 is omitted; the processing proceeds from the pre-wet modules 200 to the plating modules 400; the processing in the cleaning modules 500 is omitted; and the wafers are transferred from the plating modules 400 to the spin rinse dryers 600. PL1 to PL4 are used in a circulating manner as the tanks used (the plating modules 400). The wafers 1 to 10 are taken out of the cassettes (FOUP) in this sequence.

When a recipe is selected for the ten wafers and a job is set, the transfer scheduler 812 creates a transfer time table for the ten wafers (shown in Table and Time Table of FIG. 9A). The transfer time table herein is illustrated schematically. As shown in Table of FIG. 9A, the plating modules PL1 to PL4 are respectively allocated to the wafers 1 to 4; the plating modules PL1 to PL4 are respectively allocated to the wafers 5 to 8; and the plating modules PL1 and PL2 are respectively allocated to the wafers 9 and 10. In this state, no wafers are placed in the pre-wet modules PW1 to PW2, the plating modules PL1 to PL4 and the spin rinse dryers RD1 to RD2 (as shown in a right-side schematic diagram of the processing modules in FIG. 9A).

FIG. 9B illustrates the state that the transfer proceeds to the point when the sixth wafer 6 is taken out from FOUP. In this state, the wafers 1 to 4 are respectively placed in the plating modules PL1 to PL4, and the wafer 5 is placed in the pre-wet module PW1 (as shown in a right-side schematic diagram of the processing modules in FIG. 9B).

FIG. 9C illustrates the state that the first wafer, wafer 1 is taken out from the plating module PL1 and that contact cleaning (module cleaning) is started in the plating module PL1. The wafer 1 is placed in the spin rinse dryer RD1. The wafer 5 is planned to use the plating module PL1 next. The wafer 5 is scheduled to be placed in the plating module PL1 after completion of contact cleaning in the plating module PL1.

FIG. 9D illustrates the state that a module cleaning retry event occurs in the plating module PL1. Contact cleaning is performed in the plating module PL1 after the wafer 1 is taken out from the plating module PL1. Contact cleaning is, however, not completed by one cleaning process, and a retry occurs. In this case, the retry determination unit 813 issues a module cleaning retry event and notifies the transfer scheduler 812 of the module cleaning retry event. The transfer scheduler 812 then sets the plating module PL1 to be temporarily non-usable.

FIG. 9D also illustrates the state that the wafer 2 is taken out from the plating module PL2 and is placed in the spin rinse dryer RD2 and that contact cleaning is started in the plating module PL2.

FIG. 9E illustrates the state that the transfer time table is updated under the condition that the plating module PL1 is set to be temporarily non-usable. More specifically, as shown in Table on the left side of FIG. 9E, the transfer time table is updated, such that the wafers 5 to 7 respectively use PL2 to PL4 and that the wafers 8 to 10 respectively use PL2 to PL4. As a result, the wafer 5 is carried into the module PL2 as shown in FIG. 9F.

In the case where contact cleaning in the plating module PL1 is completed after the eighth wafer 8 is taken out from FOUP, based on the updated transfer time table, the retry determination unit 813 notifies the transfer scheduler 812 of a module cleaning completion event. The transfer scheduler 812 then returns the plating module PL1 to a usable state (as shown in FIG. 9G).

As shown in FIG. 9H, the transfer scheduler 812 then updates the transfer time table under the condition that the plating module PL1 is usable. As a result, the transfer time table is updated, such that the wafer 9 uses the plating module PL1 as shown in Table on the left side of FIG. 9H. The wafer 9 is then carried into the plating module PL1 as shown in FIG. 9I.

### <Flowchart of Transfer Scheduling>

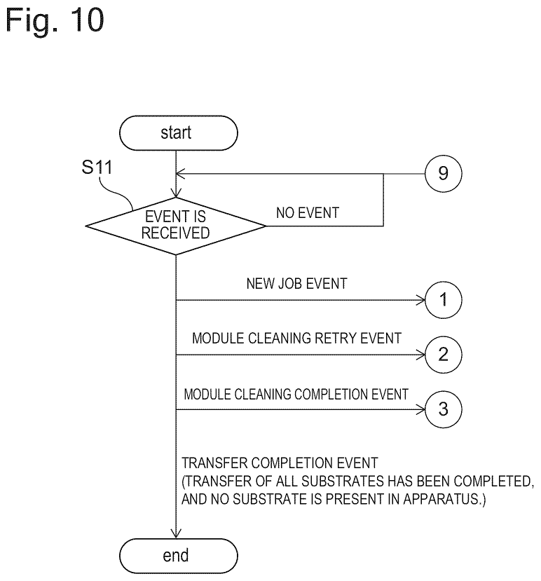

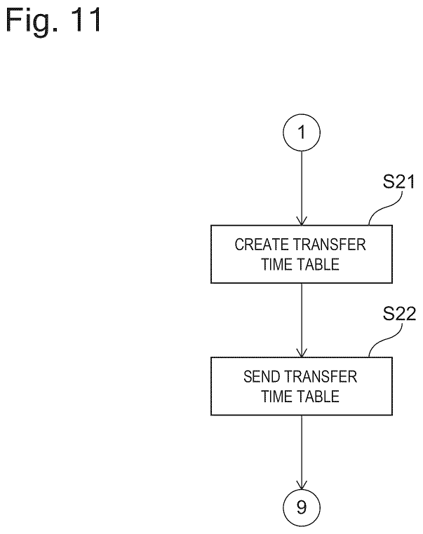

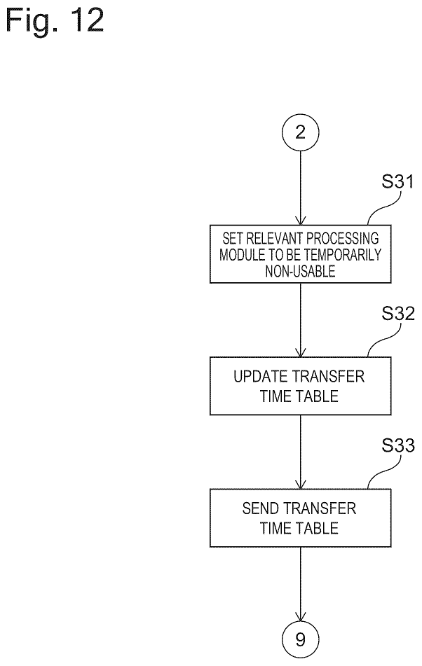

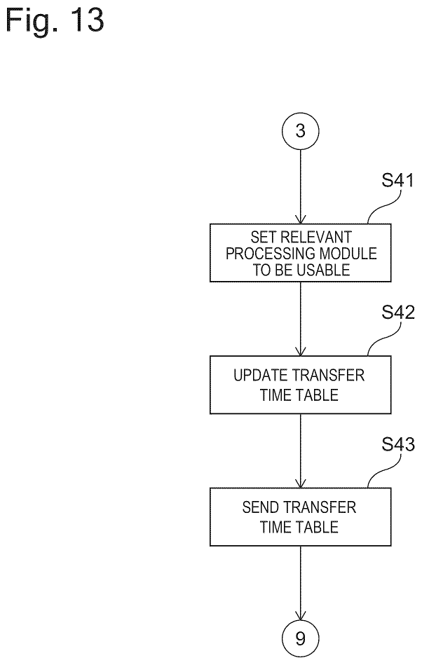

FIG. 10 is a flowchart showing a flow of transfer scheduling. FIG. 11 is a flowchart showing transfer scheduling of a new job. FIG. 12 is a flowchart showing transfer scheduling at the time of a retry of module cleaning. FIG. 13 is a flowchart showing transfer scheduling on completion of module cleaning. These processes are performed by the transfer scheduler 812.

At step S11, the transfer scheduler 812 determines whether an event is received or not. The transfer scheduler 812 repeats the processing of step S11 until an event is received.

When it is determined that a new job event is received at step S11, the transfer scheduler 812 performs transfer scheduling of the new job (shown in FIG. 11). More specifically, as shown in FIG. 11, the transfer scheduler 812 creates a transfer time table for the new job at step S21. The transfer scheduler 812 subsequently sends the created transfer time table to the device controller 820 at step S22 and then returns to step S11.

When it is determined that a module cleaning retry event is received at step S11, on the other hand, the transfer scheduler 812 performs transfer scheduling at the time of a retry of module cleaning (shown in FIG. 12). More specifically, as shown in FIG. 12, in response to receiving of a module cleaning retry event, the transfer scheduler 812 sets the relevant processing module to be temporarily non-usable at step S31. The transfer scheduler 812 updates the transfer time table under the condition that the relevant processing module is set to be temporarily non-usable at step S32. The transfer scheduler 812 sends the updated transfer time table to the device controller 820 at step S33 and then returns to step S11.

When it is determined that a module cleaning retry event is received at step S11 and the relevant processing module as the object of the module cleaning retry event has already been set to be temporarily non-usable, the transfer scheduler 812 does not perform the transfer scheduling at the time of the retry of module cleaning (shown in FIG. 12) again but terminates the processing (returns to step S11 of FIG. 10). In the case where multiple times of retries of module cleaning are performed, the transfer scheduler 812 performs the transfer scheduling at the time of the retry of module cleaning (shown in FIG. 12), when a first module cleaning retry event is received. The transfer scheduler 812 does not update the transfer schedule when a second or subsequent module cleaning retry event is received. In the course of repetition of multiple times of retries of module cleaning, when the retry determination unit 813 issues a cleaning retry event only for the first cleaning retry, the transfer scheduler 812 receives the cleaning retry event only for the first cleaning retry, performs the transfer scheduling at the time of the retry of module cleaning (shown in FIG. 12) and then receives a module cleaning completion event.

When it is determined that a module cleaning completion event is received at step S11, the transfer scheduler 812 performs transfer scheduling on completion of module cleaning (shown in FIG. 13). More specifically, as shown in FIG. 13, in response to receiving of a module cleaning completion event, the transfer scheduler 812 sets the relevant processing module corresponding to this event to be usable at step S41. The transfer scheduler 812 updates the transfer time table under the condition that the relevant processing module is set to be usable at step S42. The transfer scheduler 812 sends the updated transfer time table to the device controller 820 at step S43 and then returns to step S11.

When it is determined that a transfer completion event is received at step S11 (transfer of all the substrates has been completed and no substrate is present in the apparatus), the transfer scheduler 812 terminates the transfer scheduling (to end of FIG. 10).

### (Another Substrate Processing Apparatus)

FIG. 14 is a plan view illustrating the overall configuration of another substrate processing apparatus. FIG. 14 illustrates an exemplified configuration of a vertical plating apparatus. The above embodiment illustrates the horizontal or traverse plating apparatus 1000 as an example of the substrate processing apparatus. The configuration of the above embodiment is, however, also applicable to a vertical plating apparatus 1000-1.

The plating apparatus 1000-1 includes a loading/unloading station 101A-1 configured to load a substrate as an object to be processed to a substrate holder 11-1 or to unload a substrate from the substrate holder 11-1; a processing station 101B-1 configured to process the substrate; and a control module 150-1. In this illustrated example, the substrate is a rectangular substrate. The substrate herein may, however, be a substrate in a circular shape, in a polygonal shape such as a rectangular shape, or in any of other arbitrary shapes. The substrate herein may be a semiconductor wafer, a glass substrate, a liquid crystal substrate, a printed circuit board or any of other arbitrary objects to be processed. The control module 150-1 has a similar configuration to that of the control module 800 of the embodiment described above and is enabled to perform transfer scheduling similar to that performed by the control module 800.

The loading/unloading station 101A-1 includes a plurality of cassette tables 102-1, transfer robots 103-1 and 104-1, cleaners 105-1 and a substrate attachment/detachment station 107-1. Cassettes (FOUP or the like), each provided with a substrate placed therein, are mounted on the respective cassette tables 102-1. According to this embodiment, the cleaner 105-1 is a rinse dryer having a drying function (cleaning and drying device/module) and is configured to clean and dry the substrate after a plating process. The cleaner 105-1 may be a type provided individually with a cleaning tank or module and a drying tank or module or may be a type provided with a common tank or module used for both a cleaning process and a drying process. According to another embodiment, the cleaner 105-1 may be replaced by a dryer configured to perform only drying. For example, an air knife configured to spray the air (the dry air, nitrogen gas or the like) to the substrate may be employed for a drying mechanism of the cleaner 105-1. The configuration of the loading/unloading station 101A-1 includes two cleaners 105-1 in this illustrated example but may include one cleaner 105-1 or three or more cleaners 105-1. One or a plurality of temporary placing tables 105 A-1 may be provided to temporarily place the substrate in the process of transferring the substrate between the transfer robot 103-1, the transfer robot 104-1 and the cleaners 105-1.

The substrate attachment/detachment station 107-1 includes one or a plurality of substrate attachment/detachment devices configured to attach a substrate to the substrate holder 11-1 and to detach a substrate from the substrate holder 11-1. In this illustrated example, the substrate attachment/detachment device is comprised of a rotation device 107A-1 and a support station 107B-1. In the state that the rotation device 107A-1 supports a second holding member 11B-1 of the substrate holder 11-1 in a horizontal attitude, a substrate is placed on the second holding member 11B-1 by the transfer robot 104-1. The rotation device 107A-1 subsequently rotates the second holding member 11B-1 with the substrate held thereon to a vertical attitude and presses the second holding member 11B-1 with the substrate thereon against a first holding member 11A-1 in a vertical attitude, which is held by the support station 107B-1. The substrate is accordingly placed between the first holding member 11A-1 and the second holding member 11B-1, and the first holding member 11A-1 and the second holding member 11B-1 are then fixed to each other by a fixation mechanism (for example, a clamp or the like) that serves to fix the first holding member 11A-1 and the second holding member 11B-1 to each other. The substrate is accordingly held by the substrate holder 11-1.

The processing station 101B-1 includes a stocker 108-1 configured to store and temporarily place the substrate holders 11-1, a substrate holder cleaning device 109-1 configured to clean the substrate holder 11-1, a pre-wet module 110-1, a temporary placing table 111-1, a pre-soak rinse module 112-1, a blow module 113-1, a rinse module 114-1, and a plating station 115-1. These respective modules or each module may commonly be called processing modules. Each of the substrate holder cleaning device 109-1, the pre-wet module 110-1, the pre-soak rinse module 112-1, the rinse module 114-1 and part or a plurality of processing modules in the plating station 115-1 may include a processing tank that holds a predetermined processing solution therein.

In the pre-wet module 110-1, the substrate is soaked in a processing solution (for example, pure water), and the air inside of an opening (for example, a resist opening) on the surface of the substrate is replaced with pure water. In the pre-soak rinse module 112-1, an oxide film on the surface of a conductive layer, such as a seed layer, formed on the surface of the substrate is etched off. The substrate after pre-soaking, together with the substrate holder 11-1, is cleaned with a cleaning liquid (for example, pure water) as a processing solution. The blow module 113-1 serves to drain the liquid from the substrate after cleaning. In the rinse module 114-1, the substrate after plating, together with the substrate holder 11-1, is cleaned with a cleaning liquid (for example, pure water) as a processing solution.

The plating station 115-1 includes a plurality of plating modules (also called cells) provided with an overflow tank (not shown). Each plating module places one substrate inside thereof and causes the substrate to be soaked in a plating solution kept inside of the plating module, so that the surface of the substrate is plated with, for example, copper. The type of the plating solution used herein is not specifically limited but may be any of various plating solutions according to the applications. In the case where one substrate is subjected to a plurality of different plating processes, an additional plating station may be provided.

The plating apparatus 1000-1 is provided with a substrate holder transfer device 120-1 that employs, for example, a linear motor system and that is placed on the side of the above modules and devices and is configured to transfer the substrate holder between these modules and devices. This substrate holder transfer device 120-1 includes one or a plurality of transporters (transfer machines) 121-1. The transporter 121-1 runs on a rail 122-1. The configuration of this illustrated example is provided with three transporters 121-1 and uses two transporter 121-1. All the three transporters are used according to the specification of the plating apparatus 1000-1 (the number of modules). Another configuration may be provided with one transporter 121-1, two transporters 121-1, or four or more transporters 121-1 and may use part or all of the transporters to transfer the substrate between the respective modules and devices. This configuration of the plating apparatus 1000-1 is only illustrative, and any other configuration may be employed.

In the plating apparatus 1000-1, the transfer robot 103-1 takes out an unprocessed substrate from a cassette placed on the cassette table 102-1 and delivers the substrate to the transfer robot 104-1 via the temporary placing table 105A. The transfer robot 104-1 carries the substrate into the substrate attachment/detachment station 107-1. In the substrate attachment/detachment station 107-1, the substrate is attached to the substrate holder 11-1 taken out from the stocker 108-1. The substrate attached to the substrate holder 11-1 is transferred by the transporter 121-1 to the pre-wet module 110-1 to be subjected to a pre-wet process. After the pre-wet process, the substrate is transferred to the pre-soak rinse module 112-1 to be subjected to a pre-soak process and a water washing process.

The substrate subjected to the water washing process is transferred by the transporter 121-1 to the plating module of the plating station 115-1 and is soaked in the plating solution. The substrate is accordingly subjected to a plating process, and a metal film is formed on the substrate. The substrate after the plating process is transferred by the transporter 121-1 to the rinse module 114-1 to be subjected to a water washing process, and is subsequently transferred to the blow module 113-1 to be subjected to a rough drying process. The substrate is then transferred by the transporter 121-1 to the substrate attachment/detachment station 107-1 and is detached from the substrate holder 11-1. The substrate detached from the substrate holder 11-1 is transferred by the transfer robot 104-1 to the cleaner 105-1 to be subjected to a cleaning and drying process and is then placed in a cassette on the cassette table 102-1 by the transfer robot 103-1. The substrate holder 11-1 is returned to the stocker 108-1 by the transporter 121-1.

### Other Embodiments

(1) The above embodiment illustrates the contact cleaning in the plating module as an example of module cleaning. The configuration of the above embodiment may be applied, on the occurrence of a retry of cleaning in any part of any module (for example, cleaning of a tank in the cleaning unit, the spin rinse dryer or the like). The configuration of the above embodiment may also be applied, on the occurrence of a retry of substrate cleaning.

(2) The above embodiment illustrates the example of updating the transfer time table, on the occurrence of a retry of cleaning in one plating module. On the occurrence of retries of module cleaning in two or more plating modules or any other processing modules in an overlapped time period, a modified configuration may repeat the processing of FIG. 10 and FIG. 12 to set the two or more processing modules to be non-usable and to update the transfer time table. On completion of module cleaning in a plurality of processing modules set to be non-usable, a modified configuration may sequentially set the processing module that has completed module cleaning to be usable again and may update the transfer schedule each time, based on the usable processing module (shown in FIG. 10 and FIG. 13).

At least the following technical concepts are provided from the description of the above embodiments.

[1] According to one aspect, there is provided an apparatus for processing a substrate, comprising: a plurality of processing modules, each being configured to perform processing of a substrate; a transfer machine configured to transfer the substrate; and a controller configured to create a transfer time table, which causes the substrate to be transferred between the plurality of processing modules and to be processed, and to control the transfer of the substrate by the transfer machine and control the processing of the substrate in each of the plurality of processing modules, based on the transfer time table, wherein when it is determined that a retry or an extension of a cleaning process is expected to occur or occurs in a first processing module out of the plurality of processing modules, the controller sets the first processing module to be non-usable and updates the transfer time table, such that a subsequent substrate does not pass through the first processing module.

On the occurrence of a retry (including an extension) of a cleaning process in any processing module, the apparatus for processing the substrate of this aspect sets the processing module to be non-usable and updates the transfer time table, such that a subsequent substrate does not pass through but goes around the processing module. This suppresses a reduction in the throughput of the apparatus and also suppresses the substrate placed in a processing module on an upstream side from exceeding an upper limit of a leaving time after processing. For example, when there is any substrate that is planned to use the processing module, the configuration of this aspect updates the transfer time table, such as to cause the substrate to pass through another processing module of an identical type, and thereby minimizes a reduction in the throughput of the apparatus.

[2] According to one aspect, in the apparatus for processing the substrate, when it is determined that the cleaning process including the retry or the extension of the cleaning process is expected to be completed or has been completed, the controller may set the first processing module to be usable and may update the transfer time table.

On completion of cleaning by the retry or the extension of cleaning, the configuration of this aspect returns the processing module to be usable again and performs the processing of the substrate by using a maximum number of usable processing modules. This configuration further suppresses a reduction in the throughput of the apparatus.

[3] According to one aspect, in the apparatus for processing the substrate, when it is determined that a retry or an extension of the cleaning process is expected to occur in a middle of the cleaning process, the controller may set the first processing module to be non-usable and may update the transfer time table.

In the middle of a first cleaning process in a processing module or in the middle of a retry or an extension of a cleaning process in the processing module, the configuration of this aspect determines that a retry or another retry of the cleaning process is required without waiting for termination of the cleaning process in progress, sets the processing module to be non-usable, and updates the transfer time table. This configuration enables the transfer time table to be updated at an earlier timing when the processing of another substrate proceeds to a minimum extent and thereby assures more effective update of the transfer time table. This configuration also readily provides a sufficient processing time for updating the transfer time table.

[4] According to one aspect, in the apparatus for processing the substrate, when it is determined that the cleaning process is expected to be completed without another retry or without any further extension in a middle of the retry or the extension of the cleaning process, the controller may set the first processing module to be usable and may update the transfer time table.

In the middle of a retry or an extension of a cleaning process, the configuration of this aspect determines that the cleaning process is expected to be successfully completed without waiting for termination of the cleaning process, sets the processing module to be usable again, and updates the transfer time table. This configuration enables the transfer time table to be updated at an earlier timing when the processing of another substrate proceeds to a minimum extent and thereby assures more effective update of the transfer time table. This configuration also readily provides a sufficient processing time for updating the transfer time table.

[5] According to one aspect, in the apparatus for processing the substrate, when it is determined that a retry or an extension of a cleaning process is expected to occur or occurs in a second processing module out of the plurality of processing modules, while the first processing module is set to be non-usable, the controller may set the second processing module to be non-usable and may update the transfer time table, such that a subsequent substrate does not pass through the first processing module or the second processing module.

On the occurrence of a retry or an extension of a cleaning process in another processing module while one processing module is set to be non-usable, the configuration of this aspect sets the another processing module to be non-usable and allows for an optimum update of the transfer time table. Even in the case where a retry or an extension of the cleaning process occurs in an overlapped time period in two or more processing modules, this configuration suppresses a reduction in the throughput of the apparatus and/or reduces the possibility that an upper limit of a leaving time after processing cannot be kept.

[6] According to one aspect, in the apparatus for processing the substrate, the cleaning process may be contact cleaning of a substrate holder in a plating module or tank cleaning in any processing module.

In any of various cleaning processes including contact cleaning of a substrate holder in a plating module, the configuration of this aspect enables the transfer time table to be updated to a more appropriate state on the occurrence of a retry or an extension.

[7] According to one aspect, there is provided a method of controlling an apparatus for processing a substrate, which comprises a plurality of processing modules, each being configured to perform processing of a substrate; and a transfer machine configured to transfer the substrate. The method of controlling the apparatus comprises: creating a transfer time table, which causes the substrate to be transferred between the plurality of processing modules and to be processed, and controlling the transfer of the substrate by the transfer machine and controlling the processing of the substrate in each of the plurality of processing modules, based on the transfer time table; and when it is determined that a retry or an extension of a cleaning process is expected to occur or occurs in a first processing module out of the plurality of processing modules, setting the first processing module to be non-usable and updating the transfer time table.

[8] According to one aspect, there is provided a storage medium configured to store therein a program that causes a computer to perform a method of controlling an apparatus for processing a substrate, which comprises a plurality of processing modules, each being configured to perform processing of a substrate; and a transfer machine configured to transfer the substrate. The program causes the computer to perform: creating a transfer time table, which causes the substrate to be transferred between the plurality of processing modules and to be processed, and controlling the transfer of the substrate by the transfer machine and controlling the processing of the substrate in each of the plurality of processing modules, based on the transfer time table; and when it is determined that a retry or an extension of a cleaning process is expected to occur or occurs in a first processing module out of the plurality of processing modules, setting the first processing module to be non-usable and updating the transfer time table.

Although the embodiments of the present invention have been described based on some examples, the embodiments of the invention described above are presented to facilitate understanding of the present invention, and do not limit the present invention. The present invention can be altered and improved without departing from the subject matter of the present invention, and it is needless to say that the present invention includes equivalents thereof. In addition, it is possible to arbitrarily combine or omit respective constituent elements described in the claims and the specification in a range where at least a part of the above-mentioned problem can be solved or a range where at least a part of the effect is exhibited.

The present application claims priority to Japanese patent application No. 2023-212458 filed on Dec. 15, 2023. The entire disclosure of Japanese patent application No. 2023-212458 filed on Dec. 15, 2023, including the specification, claims, drawings and abstract is incorporated herein by reference in its entirety.

The entire disclosures of Japanese Patent No. 7142812B (PTL 1), including the specifications, claims, drawings and abstracts are incorporated herein by reference in its entirety.

### REFERENCE SIGNS LIST

10 plating tank
16 anode
17 ionically resistive element
20 overflow tank
30 substrate holder
31 first holding member
32 second holding member
40 rotation mechanism
45 tilt mechanism
46 lift mechanism
50 contact
55 seal member
100 load port
110 transfer robot
120 aligner
130 operation device
200 pre-wet module
300 pre-soak module
400 plating module
500 cleaning module
600 spin rinse dryer
700 transfer device (transfer machine)
800 control module
810 device computer
811 operation screen application
812 transfer scheduler
820 device controller
1000 plating apparatus
PW1-PW2 pre-wet modules
PL1-PL4 plating module
RD1-RD2 spin rinse dryers

What is claimed is:

1. An apparatus for processing a substrate, comprising:
a plurality of processing modules, each being configured to perform processing of a substrate;
a transfer machine configured to transfer the substrate; and
a controller configured to create a transfer time table, which causes the substrate to be transferred between the plurality of processing modules and to be processed, and to control the transfer of the substrate by the transfer machine and control the processing of the substrate in each of the plurality of processing modules, based on the transfer time table, wherein
when it is determined that a retry or an extension of a cleaning process is expected to occur or occurs in a first processing module out of the plurality of processing modules, the controller sets the first processing module to be non-usable and updates the transfer time table, such that a subsequent substrate does not pass through the first processing module.

2. The apparatus for processing the substrate according to claim 1,
wherein when it is determined that the cleaning process including the retry or the extension of the cleaning process is expected to be completed or has been completed, the controller sets the first processing module to be usable and updates the transfer time table.

3. The apparatus for processing the substrate according to claim 1,
wherein when it is determined that a retry or an extension of the cleaning process is expected to occur in a middle of the cleaning process, the controller sets the first processing module to be non-usable and updates the transfer time table.

4. The apparatus for processing the substrate according to claim 2,
wherein when it is determined that the cleaning process is expected to be completed without another retry or without any further extension in a middle of the retry or the extension of the cleaning process, the controller sets the first processing module to be usable and updates the transfer time table.

5. The apparatus for processing the substrate according to claim 1,
wherein when it is determined that a retry or an extension of a cleaning process is expected to occur or occurs in a second processing module out of the plurality of processing modules, while the first processing module is set to be non-usable, the controller sets the second processing module to be non-usable and updates the transfer time table, such that a subsequent substrate does not pass through the first processing module or the second processing module.

6. The apparatus for processing the substrate according to claim 1,
wherein the cleaning process is contact cleaning of a substrate holder in a plating module or tank cleaning in any processing module.

7. A method of controlling an apparatus for processing a substrate, which comprises a plurality of processing modules, each being configured to perform processing of a substrate; and a transfer machine configured to transfer the substrate,
the method of controlling the apparatus comprising:
creating a transfer time table, which causes the substrate to be transferred between the plurality of processing modules and to be processed, and controlling the transfer of the substrate by the transfer machine and controlling the processing of the substrate in each of the plurality of processing modules, based on the transfer time table; and
when it is determined that a retry or an extension of a cleaning process is expected to occur or occurs in a first processing module out of the plurality of processing modules, setting the first processing module to be non-usable and updating the transfer time table.

8. A storage medium configured to store therein a program that causes a computer to perform a method of controlling an apparatus for processing a substrate, which comprises a plurality of processing modules, each being configured to perform processing of a substrate; and a transfer machine configured to transfer the substrate,
wherein the program causes the computer to perform:
creating a transfer time table, which causes the substrate to be transferred between the plurality of processing modules and to be processed, and controlling the transfer of the substrate by the transfer machine and controlling the processing of the substrate in each of the plurality of processing modules, based on the transfer time table; and
when it is determined that a retry or an extension of a cleaning process is expected to occur or occurs in a first processing module out of the plurality of processing modules, setting the first processing module to be non-usable and updating the transfer time table.
